(19) United States
(12) Patent Application Publication
(10) Pub. No.: US 2017/0219893 A1
(43) Pub. Date: Aug. 3, 2017

(54) ARRAY SUBSTRATE AND LIQUID CRYSTAL DISPLAY DEVICE USING THE ARRAY SUBSTRATE

(71) Applicant: MITSUBISHI ELECTRIC CORPORATION, Tokyo (JP)

(72) Inventor: Hiromasa MORITA, Tokyo (JP)

(73) Assignee: MITSUBISHI ELECTRIC CORPORATION, Tokyo (JP)

(21) Appl. No.: 15/286,180

(22) Filed: Oct. 5, 2016

(30) Foreign Application Priority Data
Aug. 7, 2015 (JP) 2015-157147

(51) Int. Cl. G02F 1/1362; G02F 1/1368; H01L 29/417; G02F 1/1343

(52) U.S. Cl. CPC G02F 1/136227; G02F 1/136286; G02F 1/134309; G02F 1/1368; H01L 29/41733; G02F 2201/123; G02F 2001/134318; G02F 2201/121; G02F 2201/122

(57) ABSTRACT

An array substrate includes a substrate; a scanning wiring and a signal wiring, which are provided to the substrate and cross to each other; a switching element, which is connected to the scanning wiring and the signal wiring; an electrode conductive film, which covers an upper surface of a drain electrode and an end portion of the drain electrode of the switching element and extends to form a lower electrode; an interlayer insulation film, which covers the switching element and the electrode conductive film and has an opening which exposes at least a part of the end portion of the drain electrode; and a coating conductive film, which is formed on the interlayer insulation film and covers the opening to cover the at least part of the end portion of the drain electrode.

### CROSS-REFERENCE TO RELATED APPLICATION

This application claims priority from Japanese Patent Application No. 2015-157147 filed on Aug. 7, 2015, the entire subject matter of which is incorporated herein by reference.

### TECHNICAL FIELD

This disclosure relates to a liquid crystal display device, and, specifically, relates to electrode configuration of a fringe-field switching (FFS) liquid crystal display device.

### BACKGROUND

The fringe-field switching (FFS) mode has been used frequently as a mode of the liquid crystal display device. The FFS liquid crystal display device performs display by applying a fringe electric field (oblique electric field including lateral and vertical electric field components) to a liquid crystal layer.

In the FFS liquid crystal display device, pixel electrodes and counter electrodes are formed on an array substrate on which switching elements such as thin film transistors (TFTs) is arranged. In this case, the pixel electrode and the counter electrode are overlapped in the vertical direction with interposing an insulation film. Generally, a lower electrode has a plate shape (branched-shape in some cases) and an upper electrode has branched electrode parts electrically connected in common and gap parts formed therebetween. Each of the pixel electrode and the counter electrode is mostly formed by a transparent conductive film made of ITO (Indium Tin Oxide) or the like (see WO01/18597 (FIG. 33)).

In WO01/18597, a pixel electrode PX made of a transparent conductive film ITO1 is formed to cover a pattern end of a drain electrode SD1, and the pixel electrode PX and the drain electrode SD1 are connected electrically. Generally, since the thickness of the pixel electrode PX has a thinner than thickness of the drain electrode SD1, if the pixel electrode PX insufficiently covers a step part of the pattern end of the drain electrode SD1, the transparent conductive film constituting the pixel electrode PX may be partially broken at the step part. If such the breakage at the step part occurs, transmission of the signal voltage from the thin film transistor to the pixel electrode is obstructed, and thus display failure occurs.

A similar problem may be caused in an FFS-type array substrate formed by another manufacturing method. In the FFS type, since a pixel electrode and a counter electrode are required to be formed in different layers with interposing an insulation film, a deposition step and a photoengraving step are necessary for preparing each of these electrodes. As a result, the number of steps increases. In order to avoid such the problem, a technique of forming the FFS-type array substrate without increasing the number of steps has been developed (see JP-A-2010-191410).

The above technique is characterized that a metal film constituting source/drain electrodes, etc., is continually formed after forming a semiconductor film without patterning the semiconductor film and that separation patterning between the source/drain electrodes is sequentially performed at a time of forming a pattern of the pixel electrode. Therefore, a semiconductor layer is formed just below the source electrode and the drain electrode. Meanwhile, a transparent conductive film constituting the pixel electrode is formed just above the source electrode and the drain electrode to cover these electrodes.

In other words, the metal film constituting source/drain electrodes, etc. is formed in a vertically sandwiched between the semiconductor film and the transparent conductive film. Thus, the metal film is not formed at a region where only one of the semiconductor film and the transparent conductive film is formed. In a case of laminating the transparent conductive film constituting the pixel electrode on the metal film, the transparent conductive film is configured to be extended from the drain electrode to the pixel electrode while covering the source electrode and the drain electrode.

This configuration will be further explained. The drain electrode of the thin film transistor is required to be electrically connected to the pixel electrode. As described above, the transparent conductive film extends outside of the drain electrode pattern to form the pixel electrode while covering the drain electrode. Thus, the transparent conductive film is required to be extended to the pixel electrode over the step part of a pattern end of the drain electrode. In other words, the transparent conductive film also serves as a conduction path between the pixel electrode and the drain electrode and is required to cover the step part of the pattern end of the drain electrode. Further, as described above, since the semiconductor layer is formed just below the drain electrode, the step part of the pattern end of the drain electrode locate substantially at the same position as that of the step part of the pattern end of the semiconductor layer. Consequently, the transparent conductive film is required to be extended so as to also cover the step part of the pattern end of the semiconductor layer.

However such the coverage becomes difficult if the pattern end of the drain electrode has a vertical shape or a reverse tapered shape. Such the coverage becomes further difficult if a concave called a notch is formed at a boundary between the metal film and the semiconductor film. In any case, the coverage in a case of forming the FFS-type array substrate without increasing the number of steps becomes further difficult. If electrical connection is deteriorated due to insufficient coverage of the transparent conductive film, an electrical resistance between the drain electrode and the pixel electrode increases. As a result, signal transmission to the pixel electrode is obstructed, and thus display failure occurs.

### SUMMARY

This disclosure is to suppress display failure that occurs in a case where a conductive film constituting pixel electrode insufficiently covers a step part of a drain electrode upon forming an FFS-type array substrate.

According to an aspect of this disclosure, an array substrate includes: a substrate; a scanning wiring and a signal wiring, which are provided to the substrate and cross to each other; a switching element, which is connected to the scanning wiring and the signal wiring; an electrode conductive film, which covers an upper surface of a drain electrode and an end portion of the drain electrode of the switching element and extends to form a lower electrode; an interlayer insulation film, which covers the switching element and the electrode conductive film and has an opening which exposes at least a part of the end portion of the drain electrode; and a coating conductive film, which is formed on the interlayer insulation film and covers the opening to cover the at least part of the end portion of the drain electrode.

According to this disclosure, display failure in a liquid crystal display device can be suppressed.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a plan view schematically illustrating a liquid crystal display device according to the first embodiment;

FIG. 2 is an enlarged plan view illustrating a pixel of an array substrate of the liquid crystal display device according to the first embodiment;

FIG. 3 is a cross-sectional view of the liquid crystal display device taken along line A-A in FIG. 2;

FIG. 4 is an enlarged plan view illustrating the pixel of the array substrate of the liquid crystal display device during processes, according to the first and second embodiments;

FIG. 5 is a cross-sectional view taken along line B-B in FIG. 4 during processes;

FIG. 6 is an enlarged plan view illustrating the pixel of the array substrate of the liquid crystal display device during processes, according to the first embodiment;

FIG. 7 is a cross-sectional view taken along line C-C in FIG. 6 during processes;

FIG. 8 is an enlarged plan view illustrating the pixel of the array substrate of the liquid crystal display device during processes, according to the first embodiment;

FIG. 9 is a cross-sectional view taken along line D-D in FIG. 8 during processes;

FIG. 10 is an enlarged plan view illustrating the pixel of the array substrate of the liquid crystal display device during processes, according to the first embodiment;

FIG. 11 is a cross-sectional view taken along line E-E in FIG. 10 during processes;

FIG. 12 is an enlarged plan view illustrating the pixel of the array substrate of the liquid crystal display device during processes, according to the first embodiment;

FIG. 13 is a cross-sectional view taken along line F-F in FIG. 12 during processes;

FIG. 14 is an enlarged plan view illustrating a pixel of a display region of the liquid crystal display device according to the second embodiment;

FIG. 15 is a cross-sectional view of the liquid crystal display device taken along line G-G in FIG. 14;

FIG. 16 is an enlarged plan view illustrating the pixel of the array substrate of the liquid crystal display device during processes, according to the second embodiment;

FIG. 17 is a cross-sectional view taken along line H-H in FIG. 16 during processes;

FIG. 18 is an enlarged plan view illustrating the pixel of the array substrate of the liquid crystal display device during processes, according to the second embodiment;

FIG. 19 is a cross-sectional view taken along line J-J in FIG. 18 during processes;

FIG. 20 is an enlarged plan view illustrating a pixel of an array substrate of the liquid crystal display device according to the third embodiment;

FIG. 21 is a cross-sectional view of the liquid crystal display device taken along line K-K in FIG. 20;

FIG. 22 is an enlarged plan view illustrating a pixel of an array substrate of the liquid crystal display device according to the fourth embodiment;

FIG. 23 is a cross-sectional view of the liquid crystal display device taken along line M-M in FIG. 22;

FIG. 24 is an enlarged plan view illustrating a pixel of a display region of a liquid crystal display device according to the fifth embodiment;

FIG. 25 is an enlarged plan view illustrating the pixel of the display region of the liquid crystal display device according to the fifth embodiment;

FIG. 26 is an enlarged plan view illustrating a pixel of an array substrate of the liquid crystal display device according to the sixth embodiment;

FIG. 27 is a cross-sectional view of the liquid crystal display device taken along line N-N in FIG. 26;

FIG. 28 is an enlarged plan view illustrating a pixel of an array substrate of the liquid crystal display device according to the seventh embodiment; and

FIG. 29 is a cross-sectional view of the liquid crystal display device taken along line P-P in FIG. 28.

### DETAILED DESCRIPTION

Display devices according to embodiments of this disclosure will be explained with reference to accompanying drawings. In the figures for explaining the embodiments described below, as identical or similar portions are referred by common symbols, overlapped explanation thereof will be omitted.

### First Embodiment

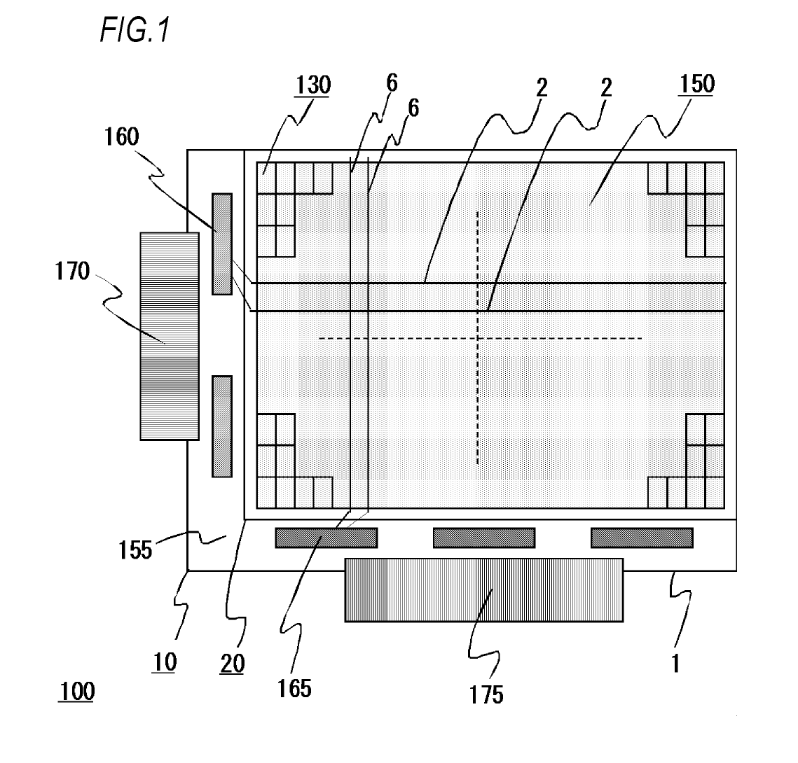

Firstly, configuration of a liquid crystal display device will be explained briefly. FIG. 1 is a plan view schematically illustrating a liquid crystal display device according to the first embodiment.

A liquid crystal display device 100 includes a display region 150 in which pixels 130 are arranged in a matrix. In the liquid crystal display device, an array substrate 10 is disposed in opposite to a counter substrate 20 so that a liquid crystal layer (not shown) is sealed therebetween. More specifically, an array substrate 10 includes scanning wirings 2 and signal wirings 6, which are arranged to cross each other so as to partition the display region into the pixels 130, TFTs and for the pixels 130 and pixel electrodes, etc., are formed. The counter substrate 20 having a color filter, a light-shielding film (black matrix) and etc., is disposed above the array substrate 10 with interposing the liquid crystal layer in an opposed manner. The two of each of the scanning wirings 2 and the signal wirings 6 shown in FIG. 1 is illustrated as an example. However, actually, a lot of each of these lines are arranged because these lines are arranged so as to partition the display region into the pixels 130.

On a transparent substrate 1 made of glass, plastics or the like, the array substrate 10 is partitioned into the display region 150 and a frame region 155 arranged at an outer circumferential periphery of the display region 150. Scanning wiring drive circuits 160 and signal wiring drive circuits 165 are arranged on the frame region 155 of the transparent substrate 1, by a COG (Chip On Glass) mounting technique. Terminals (not shown) to be connected to flexible substrates 170, 175 is provided at end portions of the transparent substrate 1. The flexible substrates 170 and 175 are connected to external circuits for supplying various kinds of voltages, clocks, image data, etc. to the scanning wiring drive circuits 160 and the signal wiring drive circuits 165, respectively. Terminals (not-shown) for supplying a reference voltage are also provided. The reference voltage is also called as a common voltage or a V-com, and is the reference voltage is applied to the counter electrode, for example, if the liquid crystal display device 100 is a lateral electric field type such as an FFS type.

In FIG. 1, a lot of each of the scanning wirings, the signal wirings and leading lines extending from the display region 150 to the output parts of the scanning wiring drive circuits 160 and the signal wiring drive circuits 165 are arranged. Also a lot of input lines, for connecting the input parts of the scanning wiring drive circuits 160 and the signal wiring drive circuits 165 to the terminals provided at the end portions of the transparent substrate 1 to be connected to the flexible substrates 170, 175, are arranged. However, for simplifying the drawing, a lot of lines are not shown in FIG. 1. Further, in a small-sized panel, since the total number of the lines is relatively small, a driving circuit integrating the scanning wiring drive circuits 160 and the signal wiring drive circuits 165 is often used. Also, the flexible substrates 170 and 175 are often integrated.

FIG. 1 shows the configuration in which the array substrate 10 is stacked on the counter substrate 20 to seal the liquid crystal therebetween. After that, the liquid crystal display device can be manufactured by connecting the external circuits to the terminals of the array substrate, adding an optical sheet such as a polarization plate and providing optical sources such as LEDs

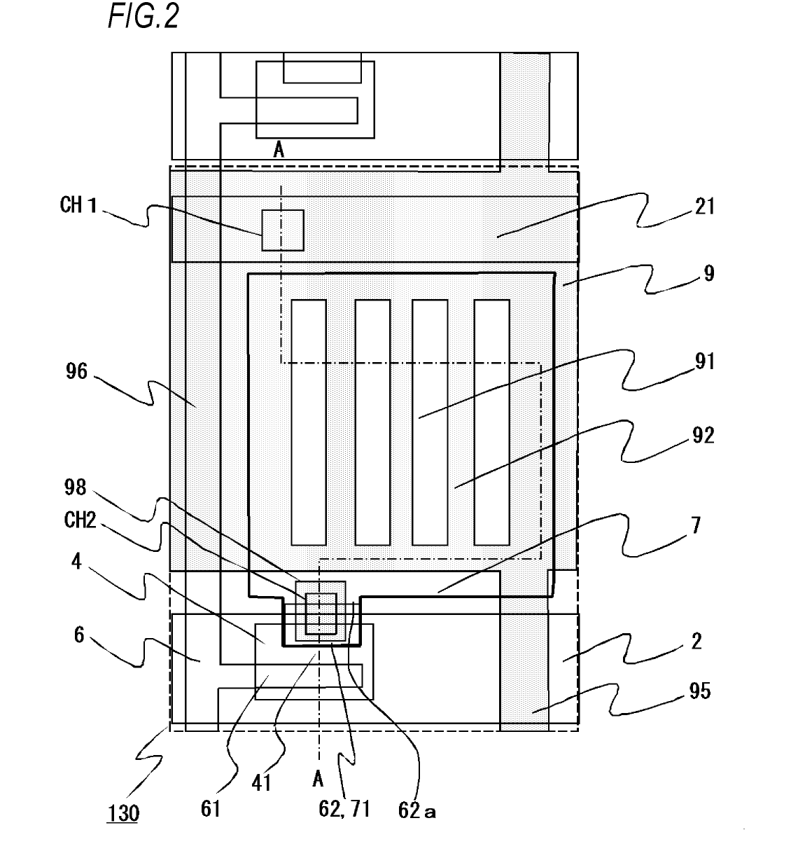

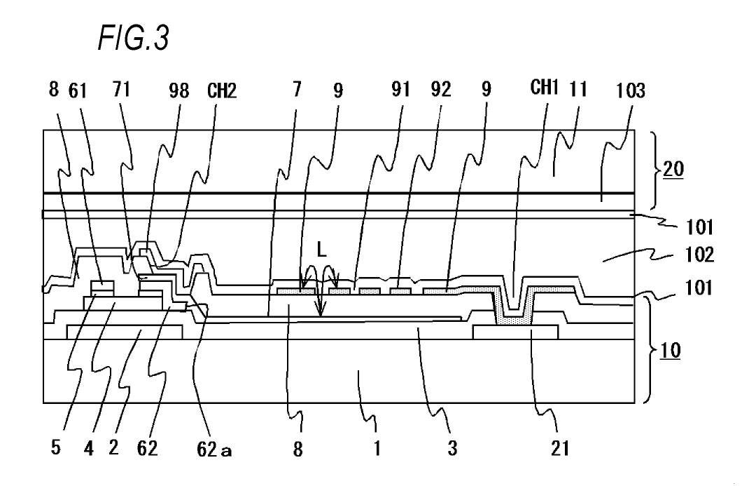

FIG. 2 is an enlarged plan view illustrating a pixel of the display region of the array substrate of the liquid crystal display device according to the first embodiment. FIG. 3 is a cross-sectional view taken along line A-A in FIG. 2. In FIG. 2, a region surrounded by a dotted line represents the pixel 130. FIG. 3 is the cross-sectional view of the liquid crystal display device including the counter electrode and the liquid crystal layer as well as the array substrate.

As shown in FIGS. 2 and 3, the scanning wiring 2 and a common wiring 21 are formed in parallel at the same layer, on the transparent substrate 1 made of glass, plastics or the like. The wirings are made of metal such as Al, Cr, Mo, Ti, Ta, W, Ni, Cu, Au or Ag, or alloy or a laminated film thereof. The common wiring 21 supplies a reference voltage to the counter electrode. A gate insulation film 3 as an insulation film made of an oxide film, a nitride film or the like is formed on the upper surfaces of the scanning wiring, the common wiring and the transparent substrate. On an upper surface region of the gate insulation film 3 corresponding to a part of the scanning wiring 2, a semiconductor film 4 and an ohmic-contact film 5 are laminated. The semiconductor film is made of silicon or oxide semiconductor material such as In—Ga—Zn—O and the ohmic-contact film is formed by implanting impurities therein. In a case where the semiconductor film 4 is made of the oxide semiconductor material, the ohmic-contact film 5 may be eliminated.

The signal wiring 6 made of metal such as Al, Cr, Mo, Ti, Ta, W, Ni, Cu, Au or Ag, or alloy or a laminated film thereof is formed to cross the scanning wiring 2. A source electrode 61 and a drain electrode 62 that are formed in the same layer as the signal wiring 6 are formed to cover the ohmic-contact film 5. The ohmic-contact film 5 between the source electrode 61 and the drain electrode 62 is removed. The semiconductor film 4 exposed between the source electrode 61 and the drain electrode 62 serves as a channel part 41. The scanning wiring 2 formed below the channel part with interposing the gate insulation film 3 acts as a gate electrode, and thus a TFT as a switching element is constituted. Hereinafter in a case of explaining configuration limited to an area near the TFT, the scanning wiring is identified with the gate electrode and sometimes called as the gate electrode 2.

In the first embodiment, a plate-shaped lower electrode 7 serves as the pixel electrode. In a case of a transmissive type, the lower electrode is formed by a transparent conductive film made of ITO (Indium Tin Oxide) or the like. In a case of a reflection type, the lower electrode is formed by a conductive film which is made of metal such as Al, Ag or Pt or alloy or a laminated film thereof and reflects visible light on the surface thereof. Parts of an electrode conductive film 71 formed by such the transparent conductive film or the metal film is directly laminated on the drain electrode 62 and extends to the outside of the drain electrode 62 to constitute the lower electrode 7.

More specifically, the electrode conductive film 71 extends to the outside of the drain electrode 62 over a step part of a pattern end 62a at which the end face of the drain electrode 62 locates and integrally forms the lower electrode 7. Since the drain electrode 62 is laminated on the electrode conductive film 71 and electrically connected to each other, the drain electrode 62 is also electrically connected to the lower electrode 7. In the first embodiment, since the electrode conductive film 71 and the lower electrode 7 are integrally formed, it appears that the electrode conductive film 71 contains the lower electrode 7 in a broad sense. However, in a case of focusing the coverage of the drain electrode 62, the term of the electrode conductive film may used to distinguish from the lower electrode 7 according to positions. A term of the pattern end generally means an end portion of the pattern and is also used as the same meaning in this embodiment. In other words, as shown in FIG. 3, the pattern end is a boundary position representing whether the lower surface of the electrode conductive film 71 contacts the gate insulation film 3 or the drain electrode 62.

An interlayer insulation film 8 made of an insulation film such as an oxide film, a nitride film or an organic resin film or a laminated film thereof is formed on an upper layer of the signal wiring 6, the source electrode 61, the drain electrode 62, the lower electrode 7 and the electrode conductive film 71.

In FIGS. 2 and 3, an upper electrode 9 serving as the counter electrode is formed on an upper surface region of the interlayer insulation film 8 corresponding to the lower electrode 7 as the pixel electrode. An orientation film 101 is formed to cover the entire surfaces of the interlayer insulation film and the upper electrodes, and is made in contact with liquid crystal 102 sealed between the orientation film and the counter substrate 20. In the counter substrate 20, a coating film 103 is formed on a lower surface of a transparent substrate 11 and an orientation film 101 is formed on a lower surface of the coating film like the array substrate.

As shown in FIG. 2, the upper electrode 9 formed by a transparent conductive film made of ITO or the like includes gap parts 91 each having no transparent conductive film and branched electrode parts 92 that are formed by the transparent conductive film and electrically connected in common. That is, the upper electrode 9 has a slit shape as described above and portions having no transparent conductive film between the branched electrode parts 92 constitute the gap parts 91. Fringe electric field L is generated between the branched electrode parts 92 and the lower electrode 7 with interposing the interlayer insulation film 8 exposed at the gap parts 91, thereby driving liquid crystal molecules of the liquid crystal 102.

The upper electrode 9 is connected to the common wiring 21 via a common contact hole CH1 and acts as the counter electrode applied with the reference voltage. The upper electrode 9 formed by the transparent conductive film made of ITO or the like has a large specific resistance as compared with those of the scanning wiring 2 and the signal wiring 6, which are formed by a metal film. Therefore, the upper electrode 9 of each pixel 130 is connected to the common wiring 21 formed by the same layer as the scanning wiring 2 in order to reduce the resistance. Although not shown, for example, a width of the scanning wiring 2 may be increased only at a portion where the common contact hole CH1 is formed.

In the first embodiment, the upper electrode 9 serving as the counter electrode is integrated with the upper electrodes 9 of the adjacent pixels 130 via connection parts 95 and 96 connected to the upper electrodes 9 in the same layer, in a direction along the signal wiring 6 (vertical direction) and a direction along the scanning wiring 2 (horizontal direction). The connection parts 95 and 96 are formed to have a lattice (mesh) shape to cover almost entirety of the scanning wirings 2 and the signal wirings 6, such that further reduction of the resistance of the upper electrode 9 is to be achieved.

Such the lattice-shaped connection parts are expanded to almost whole of the display region 150, so that the upper electrodes 9 formed at the respective pixels 130 are electrically connected to each other. In this configuration, even if the common wiring 21 is partially broken and a part of the upper electrodes 9 are not supplied with the reference voltage from the common wiring 21, such the upper electrode 9 can be supplied with the reference voltage from the upper electrode 9 of the adjacent pixel 130 via the connection parts 95 and 96. Therefore, even if the common wiring 21 is partially broken, display failure does not occur, and thus yield ratio can be improved.

Further, due to the similar reason, the common contact hole CH1 may be formed only at a part of the pixels. Further, if the upper electrodes 9 are formed to bridge all the pixels, the common wirings 21 can be omitted. Generally, since the common wiring 21 is formed by the metal film which is not capable of passing visible light, an aperture ratio can be improved advantageously by omitting the common wiring. Further, the common wiring 21 may be formed in the same layer as the upper electrode 9, and the common wiring may be formed to overlap with the scanning wiring 2 and the signal wiring 6.

The connection parts 95 and 96 cover the scanning wiring 2 or the signal wiring 6, so that leakage electric field from the scanning wiring 2 or the signal wiring 6 to the liquid crystal layer can be shielded. Thus, display failure caused by the leakage electric field likely caused near the scanning wiring 2 or the signal wiring 6 can be suppressed. Generally, a light shielding film is formed on the counter substrate 20 along the scanning wiring 2 or the signal wiring 6 to face the wirings, in order to suppress such the display failure. However, such light shielding film can be omitted.

The connection parts 95 and 96 may be configured to extend in either one of the direction along the signal wiring 6 (vertical direction) and the direction along the scanning wiring 2 (horizontal direction) to connect the upper electrodes 9 of the adjacent pixels 130.

Although the upper electrode 9 is described as above, the upper electrode 9 is not formed near the drain electrode 62. Next, configuration near the drain electrode 62 will be described.

As described above, the electrode conductive film 71 formed to cover the drain electrode 62 is extended to form the lower electrode 7, and the electrode conductive film 71 covers the step part of the pattern end 62a. Further, although the interlayer insulation film 8 is formed on the drain electrode 62 and the electrode conductive film 71, the interlayer insulation film 8 is provided with an opening CH2 exposing at least a part of the pattern end 62a. More accurately, the opening CH2 is provided so as to at least partially expose a region of the pattern end 62a which is covered by the electrode conductive film 71.

A coating conductive film 98 is formed on the interlayer insulation film 8 to cover the opening CH2. The coating conductive film 98 covers the step part of the pattern end 62a of the drain electrode 62 with interposing the electrode conductive film 71. That is, the pattern end 62a of the drain electrode 62 is covered by the electrode conductive film 71 and the coating conductive film 98 in duplicate. According to this configuration, even if the step part is not sufficiently covered by the electrode conductive film 71, since the step part is also covered by the coating conductive film 98 in duplicate, electrical connection between the drain electrode 62 and the lower electrode 7 can be maintained.

Although both the coating conductive film 98 and the upper electrode 9 are formed on the interlayer insulation film 8, voltages applied to the coating conductive film 98 and the upper electrode 9 differ from each other. In other words, a signal voltage for driving the liquid crystal is applied to the coating conductive film 98 as well as the drain electrode 62, and the reference voltage is applied to the upper electrode 9. Thus, the coating conductive film 98 and the upper electrode 9 are both formed on the interlayer insulation film 8 but disposed apart from each other.

In FIGS. 2 and 3, the pattern end 62a of the drain electrode 62 locates outside of the scanning wiring 2, and the coating conductive film 98 covers not only the pattern end 62a of the drain electrode 62 but also a step part of a pattern of the scanning wiring 2. According to this configuration, even if the step part of pattern of the scanning wiring 2 is not sufficiently covered by the electrode conductive film 71, the coverage of this step part can be improved by the coating conductive film 98 advantageously.

The coating conductive film 98 may be formed to cover only the pattern end 62a of the drain electrode 62. Further, the pattern end 62a may be located within the scanning wiring 2. If the drain electrode 62 formed by non-transmissive material locates only within the scanning wiring 2, a numerical aperture can be improved advantageously.

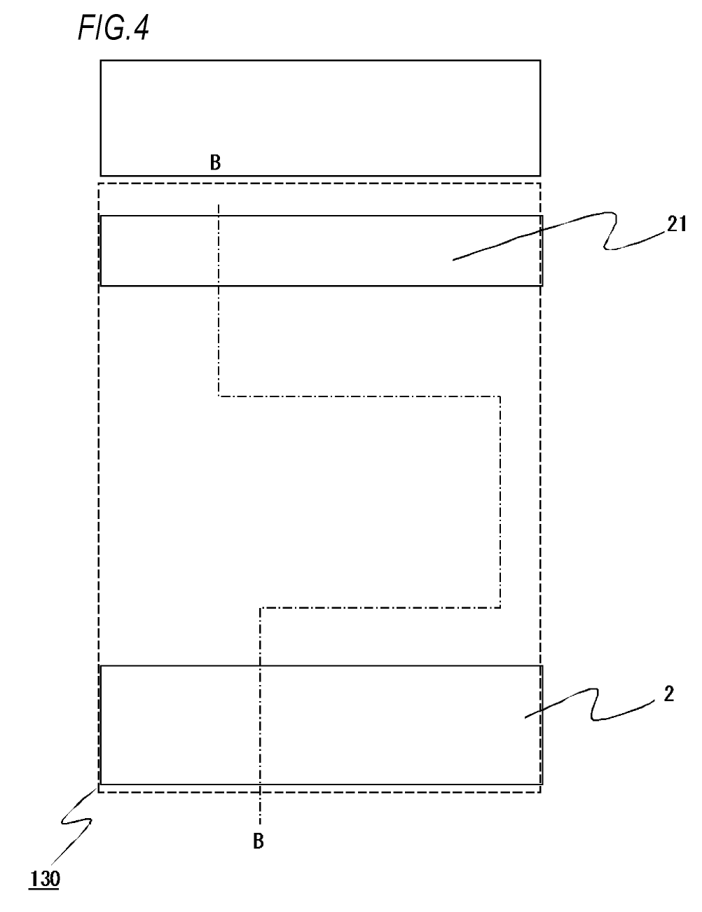

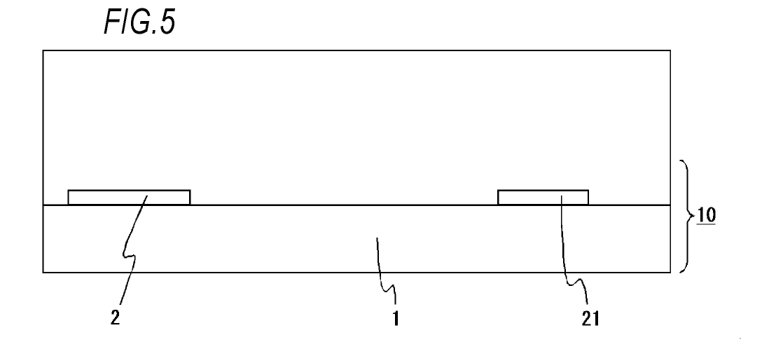

Hereinafter, a manufacturing method of the array substrate will be explained with reference to FIGS. 4 to 13. Similarly to FIG. 2, each of FIGS. 4, 6, 8, 10 and 12 is an enlarged plan view illustrating a pixel of the array substrate of the liquid crystal display device, during respective manufacturing processes. Similarly to FIG. 3, each of FIGS. 5, 7, 9, 11 and 13 is a cross-sectional view of a portion corresponding to a portion taken along line A-A in FIG. 2, during respective manufacturing processes.

Firstly, by a film forming method such as sputtering, the first metal film made of metal such as Al, Cr, Mo, Ti, Ta, W, Ni, Cu, Au or Ag, or alloy or a laminated film thereof is formed on the transparent substrate 1, the first photoengraving process is performed, and patterning is performed to form the scanning wiring 2 and the common wiring 21. FIGS. 4 and 5 illustrate this state. FIG. 5 is a cross-sectional view taken along line B-B in FIG. 4.

Then, by a film forming method such as a plasma CVD method, the first insulation film constituting the gate insulation film 3 formed by a silicon dioxide film, a silicon nitride film or the like, the semiconductor film 4 formed by a silicon film or the like, and the ohmic-contact film 5 are sequentially formed, and then patterning is performed.

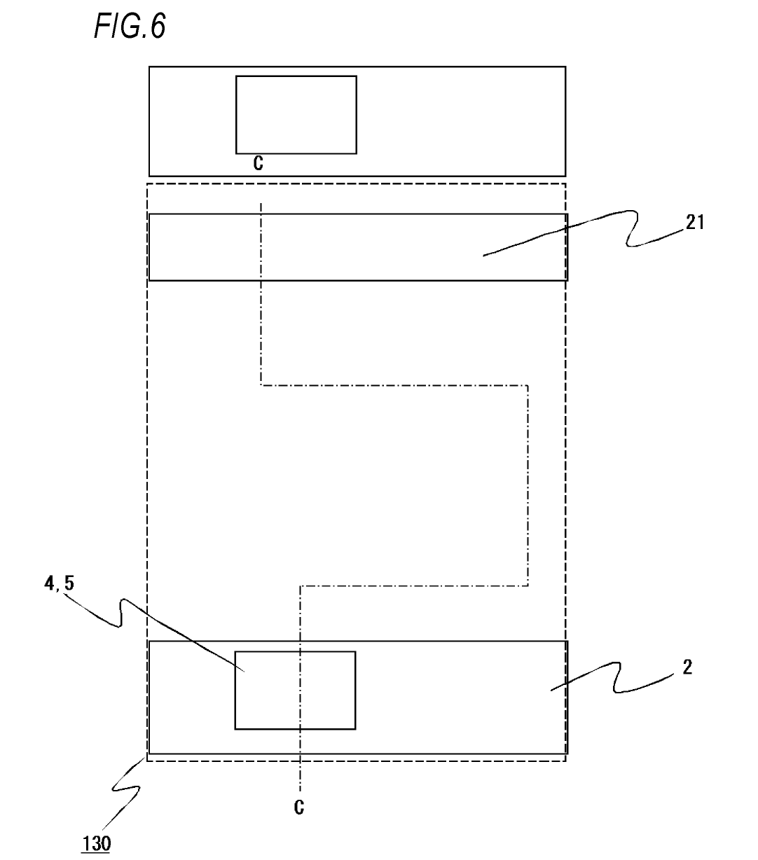

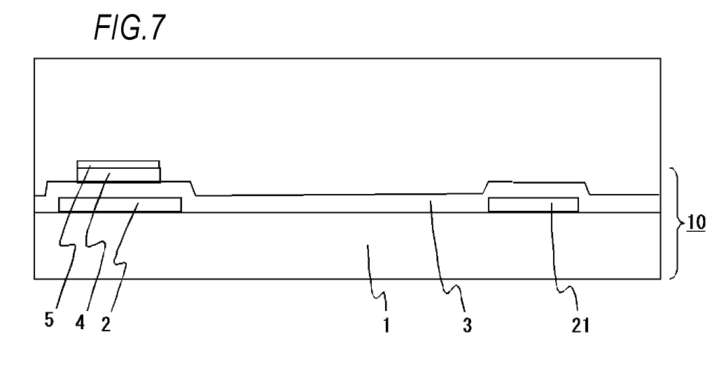

After performing the second photoengraving process, this patterning is sequentially performed with respect to the ohmic-contact film 5 and the semiconductor film 4. According to material of the film to be etched, a dry etching method, a wet etching method or the like is suitably employed as an etching method at the time of this patterning. The etching may be collectively performed by using only etching means having a larger etching selectivity with respect to the gate insulation film 3. After this patterning, a pattern of the semiconductor film 4 containing the channel part 41 of the TFT is formed. In this manner, configuration shown in FIGS. 6 and 7 is formed. FIG. 7 is a cross-sectional view taken along line C-C in FIG. 6.

Next, the second metal film made of metal such as Al, Cr, Mo, Ti, Ta, W, Ni, Cu, Au or Ag, or alloy or a laminated film thereof is formed by pattering, and then patterning is performed.

This patterning is performed with respect to this metal film after performing the third photoengraving process. According to material of the film to be etched, a dry etching method, a wet etching method or the like is suitably employed, as an etching method at the time of this patterning. The etching may be performed by using etching means having a larger etching selectivity with respect to the gate insulation film 3 and the ohmic-contact film 5. After this patterning, the source electrode 61, the drain electrode 62 and the signal wiring 6 integrally connected to the source electrode 61 are formed. The source electrode 61 and the drain electrode 62 are separated and opposed on the semiconductor film 4 serving as the channel part 41 of the TFT. At this time, the pattern end 62a, which becomes the pattern end of the drain electrode 62 to be covered by the electrode conductive film at the later stage, is also formed.

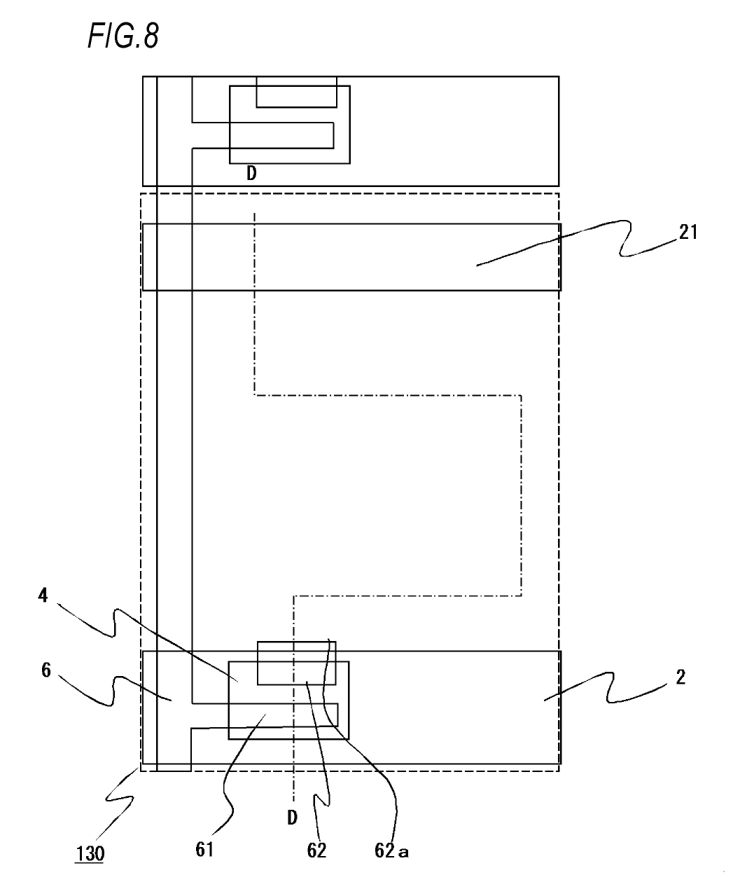

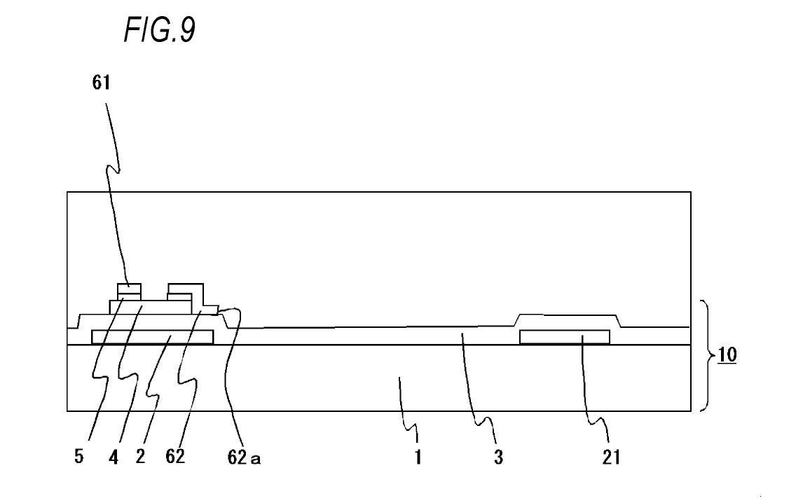

Subsequently, the exposed ohmic-contact film 5 is etched by using the second metal film as a mask. The ohmic-contact film 5 between the source electrode 61 and the drain electrode 62 is also removed, and the respective electrodes are separated by the semiconductor film 4 constituting the channel part 41. In this manner, configuration shown in FIGS. 8 and 9 is formed. FIG. 9 is a cross-sectional view taken along line D-D in FIG. 8.

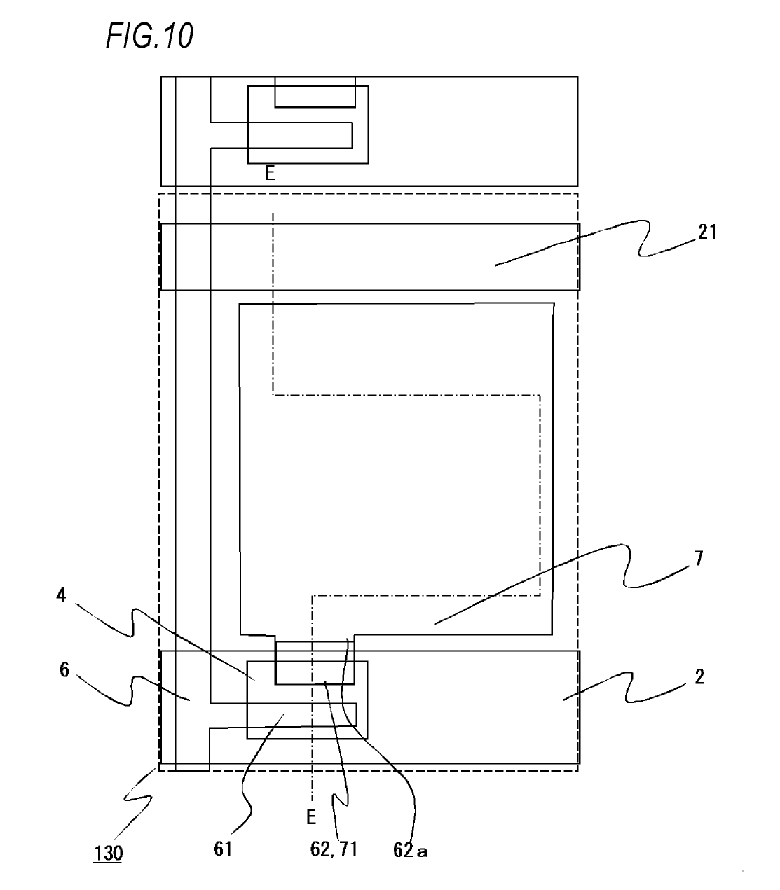

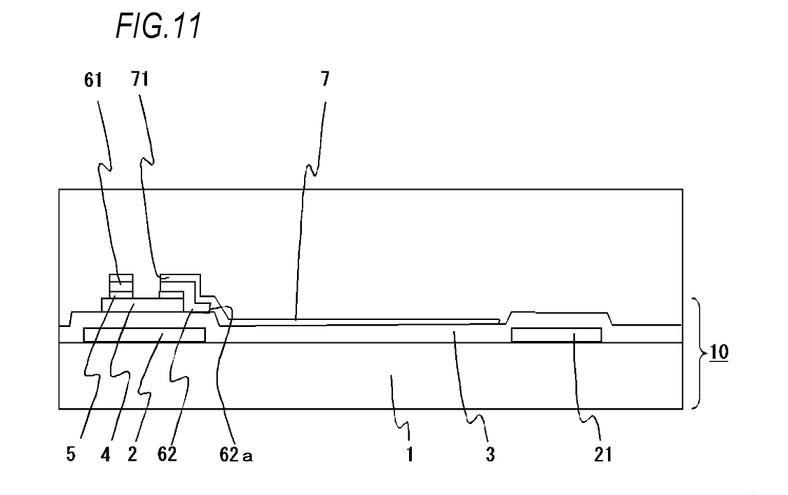

Next, after forming the first transparent conductive film made of ITO, IZO (Indium Zinc Oxide) or the like by sputtering, the fourth photoengraving process and patterning are performed. Thereafter, the first transparent conductive film is patterned so as to form the electrode conductive film 71 which is at least partially laminated on the drain electrode 62 and extends therefrom to form the pixel electrode (the lower electrode 7) on the gate insulation film 3. In this manner, configuration shown in FIGS. 10 and 11 is formed. FIG. 11 is a cross-sectional view taken along line E-E in FIG. 10.

Subsequently, the second insulation film is formed as the interlayer insulation film 8 on the films, etc. For example, an inorganic insulation film made of silicon nitride, silicon dioxide or the like is formed, as the interlayer insulation film 8, over the entire surface of the transparent substrate 1 by a CVD method or the like. As a result, the lower electrode 7 and the electrode conductive film 71 are covered by the interlayer insulation film 8. Further, the channel region of the semiconductor film 4 is covered by the interlayer insulation film 8.

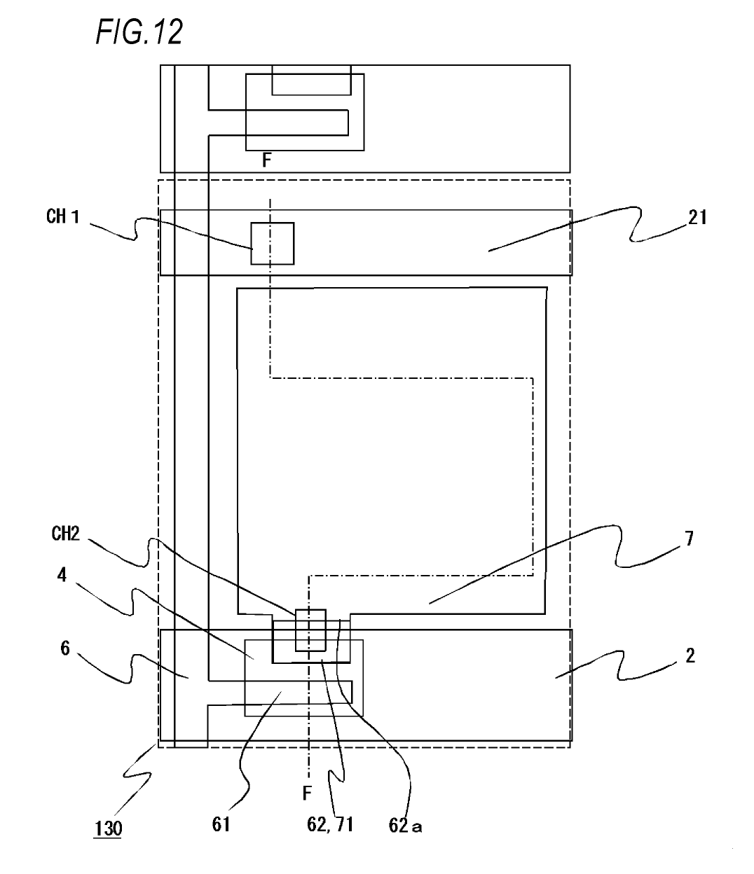

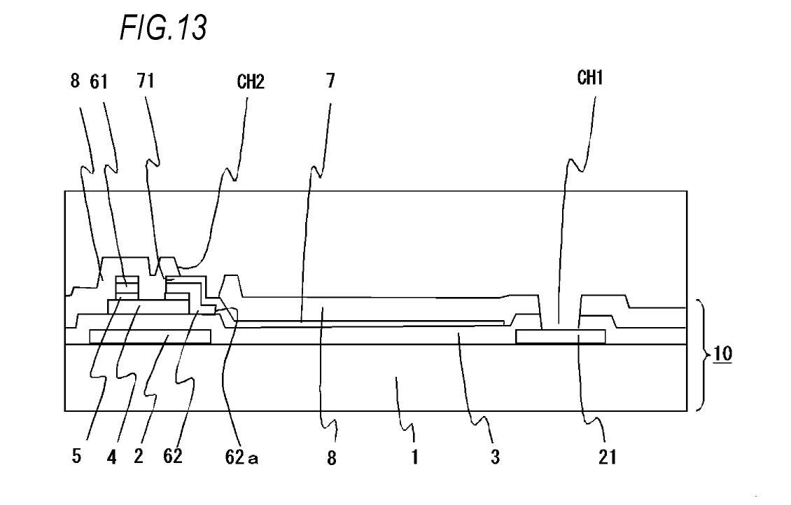

Thereafter, the contact hole and the opening part are formed at the interlayer insulation film 8 and the gate insulation film 3 by a fifth photoengraving process. The contact hole and the opening part are at least provided at the common wiring 21 and the portion where the electrode conductive film 71 covers the pattern end 62a, respectively. When the common contact hole CH1 reaching the common wiring 21 is formed, the common wiring 21 is partially exposed. The opening CH2 is provided so as to at least partially expose the region of the pattern end 62a which is covered by the electrode conductive film 71. In this manner, configuration shown in FIGS. 12 and 13 is formed. FIG. 13 is a cross-sectional view taken along line F-F in FIG. 12.

In a case where the gate insulation film 3 and the interlayer insulation film 8 are formed by the same material, it is preferable to not expose the gate insulation film 3, which is not covered by the electrode conductive film 71, in the opening CH2. At the time of forming the opening CH2 in the interlayer insulation film 8, if the gate insulation film 3 below the interlayer insulation film 8 is also etched, the coating conductive film 98 and the scanning wiring 2 may be short circuited. Of course, this problem does not occur in a case where the gate insulation film 3 and the interlayer insulation film 8 are formed by different materials and the process of forming the opening CH2 does not etch the gate insulation film 3 below the interlayer insulation film.

In the frame region 155, terminals (not shown) to be connected to the scanning wiring drive circuit 160 and the signal wiring drive circuit 165 are formed by the same layers as those of the scanning wiring 2 and the signal wiring 6, respectively. Thus, in the fifth photoengraving process, together with the common contact hole CH1 reaching the common wiring 21, a contact hole (not shown) reaching these terminals are formed in the interlayer insulation film 8 and the gate insulation film 3.

Next, the second transparent conductive film made of ITO, IZO or the like is formed on the interlayer insulation film 8 over the entire surface of the transparent substrate 1 by sputtering, etc. Then, the second transparent conductive film is patterned by a sixth photoengraving process. As shown in FIGS. 2 and 3, the upper electrode 9 having the slits is formed to face to the lower electrode 7 with interposing the interlayer insulation film 8 so as to be connected to the common wiring 21 via the common contact hole CH1.

Simultaneously with the forming of the upper electrode 9, the coating conductive film 98 is also formed to cover the opening CH2. The coating conductive film 98 is formed so as to be connected to the electrode conductive film 71 covering the pattern end 62a via the opening CH2 opened in the interlayer insulation film 8 and also to cover the step part of the pattern end 62a. According to this configuration, even if the step part is not sufficiently covered by the electrode conductive film 71, since the step part is also covered by the coating conductive film 98, electrical connection between the drain electrode 62 and the lower electrode 7 can be maintained.

In the opening CH2, the coating conductive film 98 may not cover the exposed electrode conductive film 71 entirely but may cover partially. However, it should be considered that if the electrode conductive film 71 and the upper electrode 9 are formed by the same material and there is no etching selectivity, the exposed electrode conductive film 71 is also removed by the etching at the time of patterning the upper electrode 9 and the coating conductive film 98.

Although not shown, in the frame region 155, a gate terminal pad connected to the gate terminal via the contact hole is formed by the second transparent conductive film as well as the upper electrode 9. Also, a source terminal pad connected to the source terminal via the contact hole is formed by the second transparent conductive film as well as the upper electrode 9.

### Second Embodiment

The first embodiment is explained as to the configuration where this disclosure is applied to the FFS-type array substrate. The second embodiment is explained as to configuration where this disclosure is also applied to the FFS-type array substrate, but this embodiment differs from the first embodiment in a point that the number of the photoengraving processes in the manufacturing method is reduced.

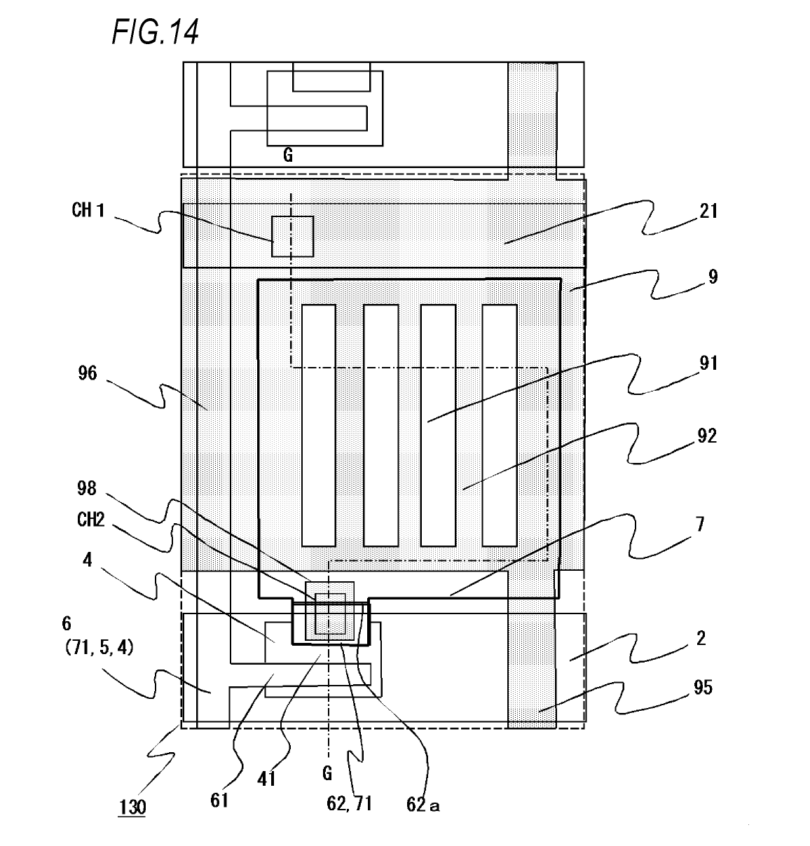

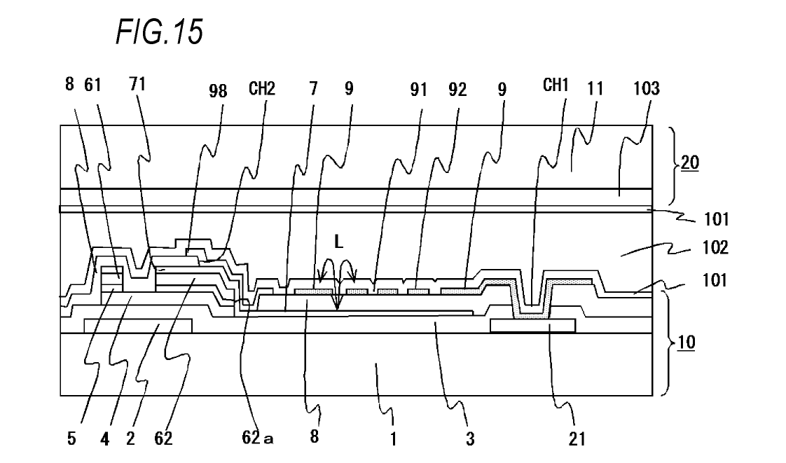

Each of FIGS. 14 and 15 is an enlarged plan view illustrating a pixel within a display region of the array substrate of the liquid crystal display device according to the second embodiment. FIG. 15 is a cross-sectional view taken along line G-G in FIG. 14.

As shown in FIGS. 14 and 15, a scanning wiring 2 and a common wiring 21 are formed side by side in the same layer, on the transparent substrate 1 made of glass, plastics or the like. The scanning wiring 2 is made of metal such as Al, Cr, Mo, Ti, Ta, W, Ni, Cu, Au or Ag, or alloy or a laminated film thereof. The common wiring 21 is supplied with a reference voltage and connected to an upper electrode acting as a counter electrode. A gate insulation film 3 as an insulation film made of an oxide film, a nitride film or the like is formed on the upper surfaces of the scanning wiring, the common wiring and the transparent substrate. On an upper surface region of the gate insulation film 3 corresponding to a part of the scanning wiring 2, a semiconductor film 4 and an ohmic-contact film 5 are laminated. The semiconductor film is made of silicon or oxide semiconductor material such as In—Ga—Zn—O and the ohmic-contact film is formed by implanting impurities therein are laminated.

A signal wiring 6 made of metal such as Al, Cr, Mo, Ti, Ta, W, Ni, Cu, Au or Ag, or alloy or a laminated film thereof is formed to cross the scanning wiring 2. The semiconductor film 4 and the ohmic-contact film 5 are laminated below the signal wiring 6. A source electrode 61 and a drain electrode 62 formed in the same layer as the signal wiring 6 are also laminated on the semiconductor film 4 and the ohmic-contact film 5. The ohmic-contact film 5 between the source electrode 61 and the drain electrode 62 is removed, and the semiconductor film exposed therebetween serves as a channel part 41. The scanning wiring 2 formed below the channel part acts as a gate electrode, and thus a TFT as a switching element is constituted.

Also in the second embodiment, a plate-shaped lower electrode 7 serves as a pixel electrode. In a case of the transmissive type, the lower electrode is formed by a transparent conductive film made of ITO or the like. In a case of the reflection type, the lower electrode is formed by a conductive film which is made of metal such as Al, Ag or Pt or alloy or a laminated film thereof and reflects visible light on the surface thereof. An electrode conductive film 71 formed by the transparent conductive film or the metal film is directly laminated on the drain electrode 62 and is extended to the outside of the drain electrode 62, thereby constituting the lower electrode 7. More specifically, the electrode conductive film 71 extends to the outside of the drain electrode 62 over a step part of a pattern end 62a of the drain electrode 62, thereby constituting the lower electrode 7. Thus, the lower electrode 7 and the drain electrode 62 are electrically connected. Further, in the second embodiment, the electrode conductive film 71 is also formed just above the source electrode 61 and the signal wiring 6.

An interlayer insulation film 8 made of an insulation film such as an oxide film, a nitride film or an organic resin film or a laminated film thereof is formed on an upper layer of the signal wiring 6, the source electrode 61, the drain electrode 62, the lower electrode 7 and the electrode conductive film 71.

An upper electrode 9 serving as the counter electrode is formed on an upper surface region of the interlayer insulation film 8 corresponding to the lower electrode 7 as the pixel electrode. As shown in FIG. 15, the upper electrode 9 formed by a transparent conductive film made of ITO or the like includes gap parts 91 each having no transparent conductive film and branched electrode parts 92 that are formed by the transparent conductive film and electrically connected in common. That is, the upper electrode 9 has a slit shape and portions having no transparent conductive film between the branched electrode parts 92 constitute the gap parts 91. Fringe electric field L is generated between the branched electrode parts 92 and the lower electrode 7 with interposing the interlayer insulation film 8 exposed at the gap parts 91, thereby driving liquid crystal molecules of the liquid crystal 102.

As shown in FIGS. 14 and 15, the upper electrode 9 is connected to the common wiring 21 via a common contact hole CH1 and acts as the counter electrode applied with the reference voltage. The upper electrode 9 formed by the transparent conductive film made of ITO or the like has a large specific resistance as compared with the scanning wiring 2 and the signal wiring 6 that are formed by a metal film. Therefore, the upper electrode 9 of each pixel 130 is connected to the common wiring 21 formed by the same layer as the scanning wiring 2 in order to reduce the resistance. Similarly to the first embodiment, the common contact hole CH1 may be formed only a part of the pixels.

Also in the second embodiment, the upper electrode 9 serving as the counter electrode is integrated with the upper electrodes 9 of the adjacent pixels 130 via connection parts 95 and 96 connected to the upper electrodes 9 in the same layer, in a direction along the signal wiring 6 (vertical direction) and a direction along the scanning wiring 2 (horizontal direction). Since the connection parts 95 and 96 are configured to have a lattice (mesh) shape to cover almost entirety of the scanning wirings 2 and the signal wirings 6, further reduction of the specific resistance of the upper electrode 9 is achieved.

According to such the lattice-shaped connection parts, even if the common wiring 21 is partially broken and so the upper electrodes 9 are partially not supplied with the reference voltage from the common wiring 21, such the upper electrode 9 can be supplied with the reference voltage from the upper electrode 9 of the adjacent pixel 130 via the connection parts 95 and 96. Consequently display failure does not occur and hence yield can be improved.

Since the connection parts 95 and 96 cover the scanning wiring 2 or the signal wiring 6, leakage electric field from the scanning wiring 2 or the signal wiring 6 to the liquid crystal layer can be shielded. Thus, display failure caused by the leakage electric field likely generated near the scanning wiring 2 or the signal wiring 6 can be suppressed. Generally, a light shielding film is formed on the counter substrate 20 in an opposed manner along the scanning wiring 2 or the signal wiring 6 in order to suppress such the display failure, this light shielding film can be eliminated in this case.

The connection parts 95 and 96 may be formed to extend in either one of the direction along the signal wiring 6 (vertical direction) and the direction along the scanning wiring 2 (horizontal direction) so as to connect the upper electrodes 9 of the adjacent pixels 130.

Although explanation is made as to the upper electrode 9, the upper electrode 9 is not formed near the drain electrode 62. Next, configuration near the drain electrode 62 will be described.

Also in the second embodiment, the electrode conductive film 71 formed to cover the drain electrode 62 is extended to form the lower electrode 7, and the electrode conductive film 71 covers the step part of the pattern end 62a. Further, in the second embodiment, the configuration of the pattern end 62a differs from that of the first embodiment. Specifically, in the second embodiment, the layer having the pattern end 62a is not limited to the drain electrode 62 but also each of the layers of the ohmic-contact film 5 and the semiconductor film 4 has its pattern end at the same position. That is, in the second embodiment, the step part to be covered by the electrode conductive film 71 includes a lamination of the drain electrode 62, the ohmic-contact film 5 and the semiconductor film 4. Although the first embodiment can be configured so as to have this structure, the second embodiment is configured in a manner where respective pattern ends of the drain electrode 62, the ohmic-contact film 5 and the semiconductor film 4 are aligned at the pattern end 62a by a manufacturing method described later.

Further, although the interlayer insulation film 8 is formed above the drain electrode 62 and the electrode conductive film 71, the interlayer insulation film 8 is provided with an opening CH2 exposing at least a part of the pattern end 62a. More accurately, the opening CH2 is provided so as to at least partially expose a region of the pattern end 62a which is covered by the electrode conductive film 71.

A coating conductive film 98 is formed on the interlayer insulation film 8 to cover the opening CH2. The coating conductive film 98 covers the step part of the pattern end 62a of the drain electrode 62 with intereposing the electrode conductive film 71. That is, the pattern end 62a of the drain electrode 62 is covered by the electrode conductive film 71 and the coating conductive film 98 in duplicate.

According to this configuration, even if the step part is not sufficiently covered by the electrode conductive film 71, since the step part is also covered by the coating conductive film 98 in duplicate, electrical connection between the drain electrode 62 and the lower electrode 7 can be maintained.

Although both the coating conductive film 98 and the upper electrode 9 are formed on the interlayer insulation film 8, voltages applied to the coating conductive film 98 and the upper electrode 9 differ. In other words, a signal voltage for driving the liquid crystal is applied to the coating conductive film 98 as well as the drain electrode 62, and the reference voltage is applied to the upper electrode 9. Thus, the pattern of the coating conducive film and the pattern of the upper electrode are disposed apart from each other.

Next, a manufacturing method of this array substrate will be explained. As shown in FIGS. 14 and 15, by film forming method such as sputtering, the first metal film made of metal such as Al, Cr, Mo, Ti, Ta, W, Ni, Cu, Au or Ag, or alloy or a laminated film thereof is formed on the transparent substrate 1. Then the first metal film is subjected to the first photoengraving process, and then patterning is performed, whereby the scanning wiring 2 and the common wiring 21 are formed.

Then, by a film forming method such as a plasma CVD method, the first insulation film constituting the gate insulation film 3 formed by a silicon dioxide film, a silicon nitride film or the like, the semiconductor film 4 formed by a silicon film or the like, and the ohmic-contact film 5 are continuously formed, and then patterning is performed. The processes described above are same as those of the first embodiment. Next, the second metal film made of metal such as Al, Cr, Mo, Ti, Ta, W, Ni, Cu, Au or Ag, or alloy or a laminated film thereof is formed by sputtering, and then patterning is performed.

This patterning is performed with respect to a laminated structure of the second metal film 60, the ohmic-contact film 5 and the semiconductor film 4 after performing the second photoengraving process. According to material of the film to be etched, a dry etching method, a wet etching method or the like is suitably employed as an etching method at the time of this patterning.

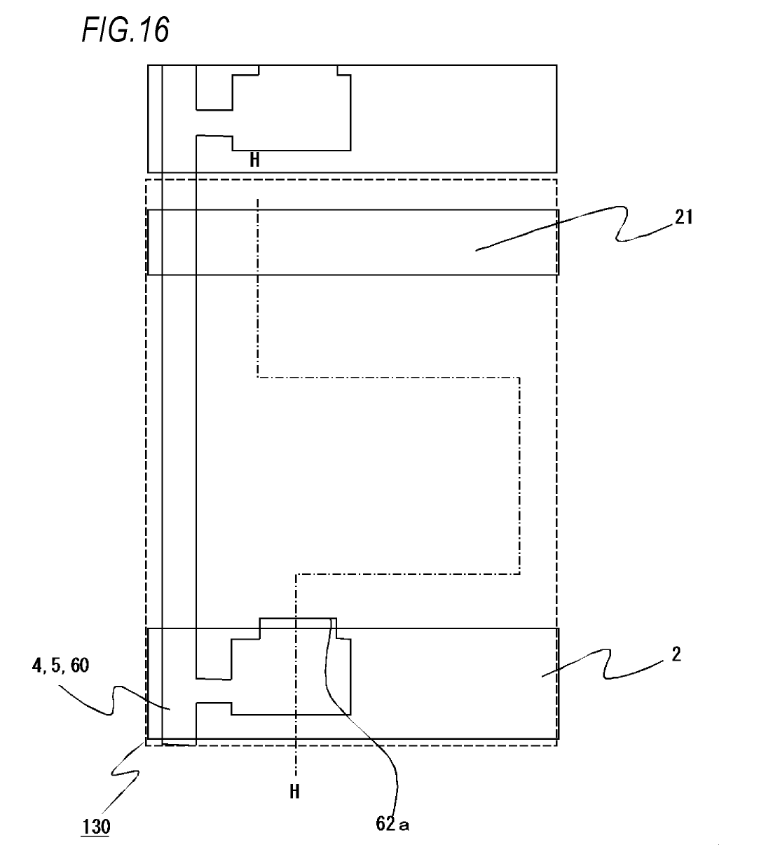

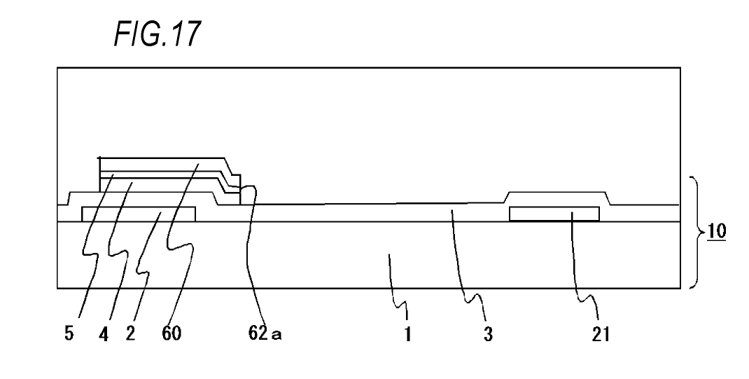

The etching may be collectively performed by using etching means having a larger etching selectivity with respect to the gate insulation film 3. In this manner, configuration shown in FIGS. 16 and 17 is formed. FIG. 17 is a cross-sectional view taken along line H-H in FIG. 16. After this patterning, such a pattern shape is formed such that the source electrode 61 and the drain electrode 62 are coupled and are integrated with the signal wiring 6 on the semiconductor film 4 serving as the channel part 41 of the TFT.

At this time, the pattern end 62a, which is the pattern end of the drain electrode 62 to be covered later by the electrode conductive film, is also formed by this patterning. As the pattern end 62a according to the second embodiment serves as the pattern ends of the semiconductor film 4 and the ohmic-contact film 5 as well as the pattern end of the drain electrode 62, a height of the step part is larger than that of the first embodiment.

Next, after forming the first transparent conductive film made of ITO or the like by sputtering, the third photoengraving process and patterning are performed. That is, the first transparent conductive film is patterned in a manner where the first transparent conductive film remains on the second metal film pattern except for the channel region of the TFT and on the forming region of the lower electrode 7. Accordingly, the first transparent conductive film remains on the signal wiring 6, the source electrode 61 and the drain electrode 62 as well as the forming region of the lower electrode 7. Also, the electrode conductive film 71 extending from the drain electrode 62 to the lower electrode 7 is formed. The electrode conductive film 71 is formed to cover the step part of the pattern end 62a.

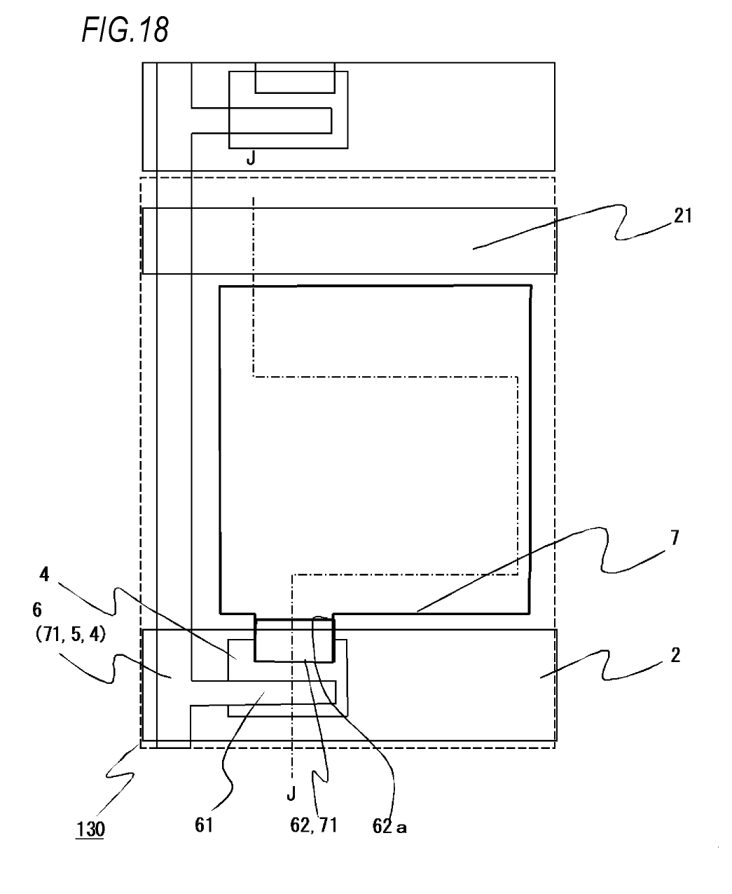

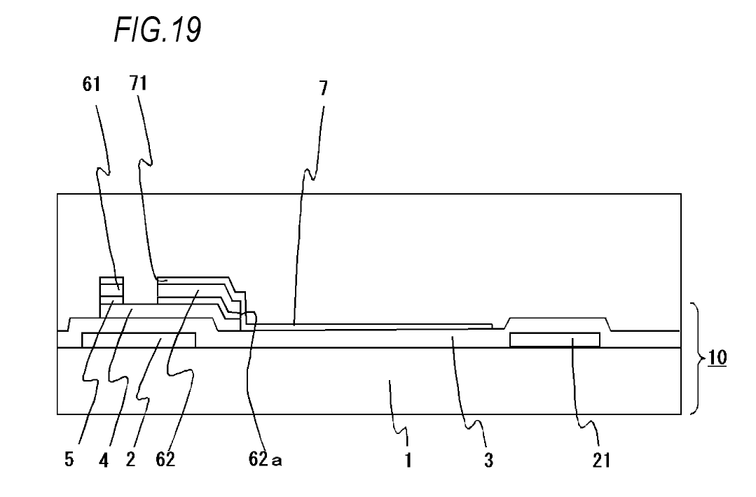

Subsequently, the second metal film and the ohmic-contact film 5 are etched by using the first transparent conductive film containing the lower electrode 7, the electrode conductive film 71, etc. as a mask. Specifically, the second metal film exposed without being covered by the lower electrode 7 or the electrode conductive film 71 is removed by the etching. Thus, the second metal film on the channel part 41 is removed, whereby the source electrode 61 and the drain electrode 62 are separated. Thereafter, the ohmic-contact film 5 exposed by the separation is etched. In this manner, configuration shown in FIGS. 18 and 19 is formed. FIG. 19 is a cross-sectional view taken along line J-J in FIG. 18.

Since the array substrate according to the second embodiment is formed in the manufacturing method described above, the second metal film constituting the source electrode 61 and the drain electrode 62 is patterned in a region sandwiched between the semiconductor film 4 and the electrode conductive film 71 in a vertical direction. The second metal film does not remain in a region where only one of the semiconductor film 4 and the electrode conductive film 71 is formed.

Subsequently, the second insulation film is formed as the interlayer insulation film 8 on the semiconductor film, the electrode conductive film, etc. Since subsequent processes are same as those of the first embodiment, explanation thereof is omitted.

The second embodiment is explained as to the case where the height of the step part of the pattern end increases at the time of reducing the number of the photoengraving processes in the manufacturing method of the array substrate. Even in such the case, the effects of this disclosure can be achieved in a manner where the coverage property of the conductive film at the step part can be improved.

### Third Embodiment

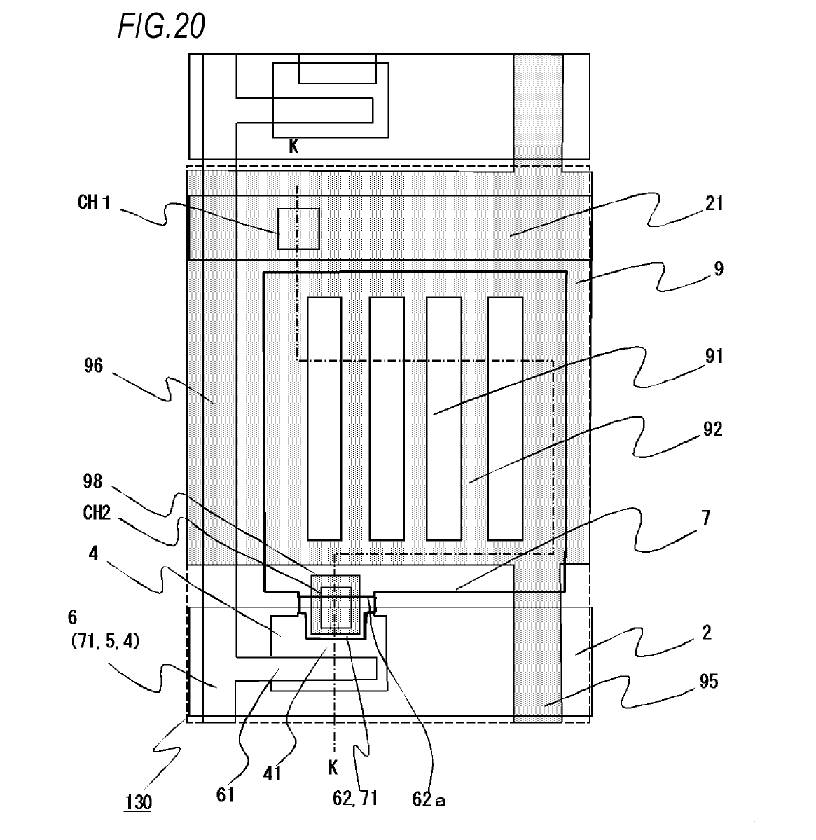

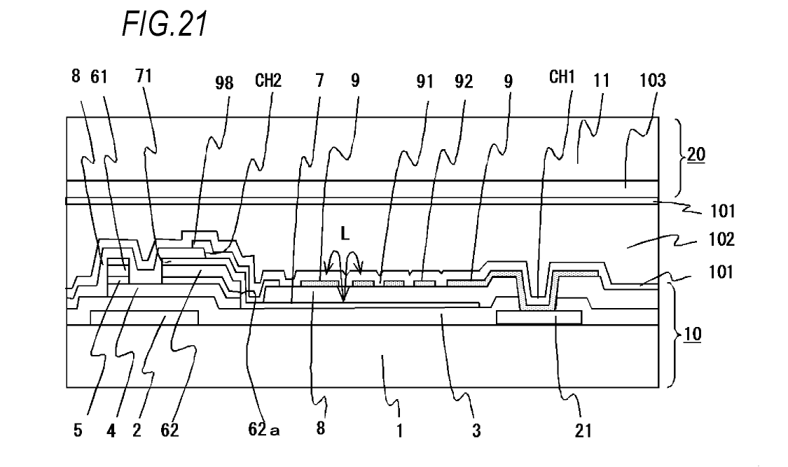

The third embodiment has configuration similar to those of the first and second embodiments and defines respective shapes of a semiconductor film, an ohmic-contact film and a drain electrode. FIG. 20 illustrates an array substrate according to the third embodiment. FIG. 21 is a cross-sectional view taken along line K-K in FIG. 20.

In the third embodiment, a drain electrode 62 is formed to have different widths on a gate electrode 2. That is, the width of the drain electrode 62 in a direction along a scanning wiring is smaller at a region in a channel part 41 as compared with a region near the edge of the gate electrode 2 (that is, a region where the drain electrode crosses the edge of the gate electrode or the scanning wiring). According to this configuration, since an area where the drain electrode 62 and the gate electrode 2 are overlapped can be reduced, display failure can be improved. More specifically, since a capacity generated between the drain electrode 62 and the gate electrode 2 can be reduced, display failure due to increase of a field through voltage or a load of gate wiring can be suppressed.

[JP0085]

By applying this disclosure also to the third embodiment, since the coverage property of conductive film at the step part of the pattern end can be improved, display failure due to insufficient coverage can be suppressed.

### Fourth Embodiment

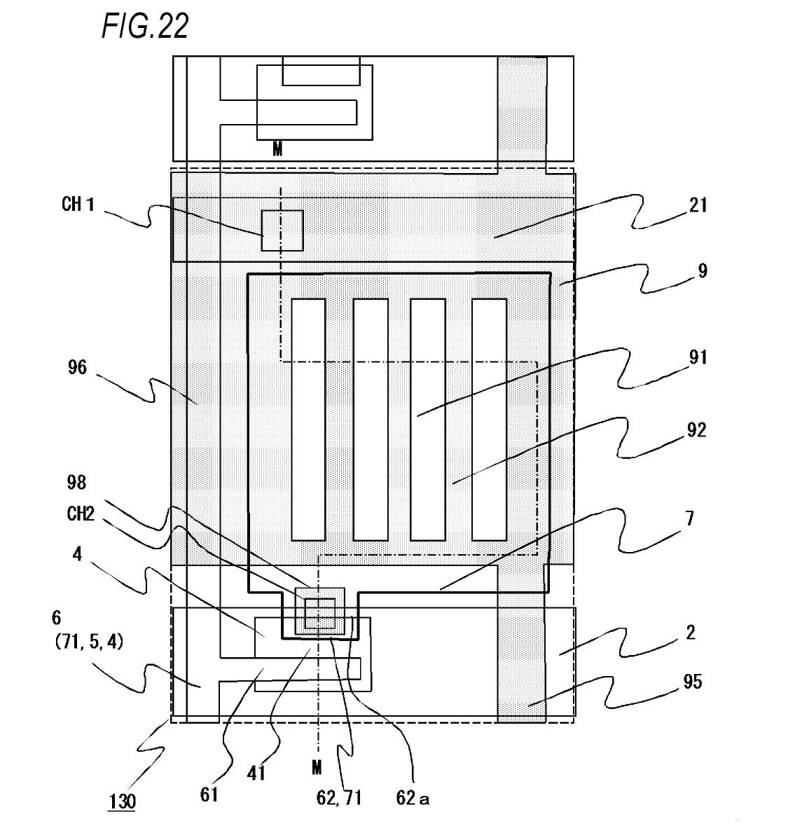

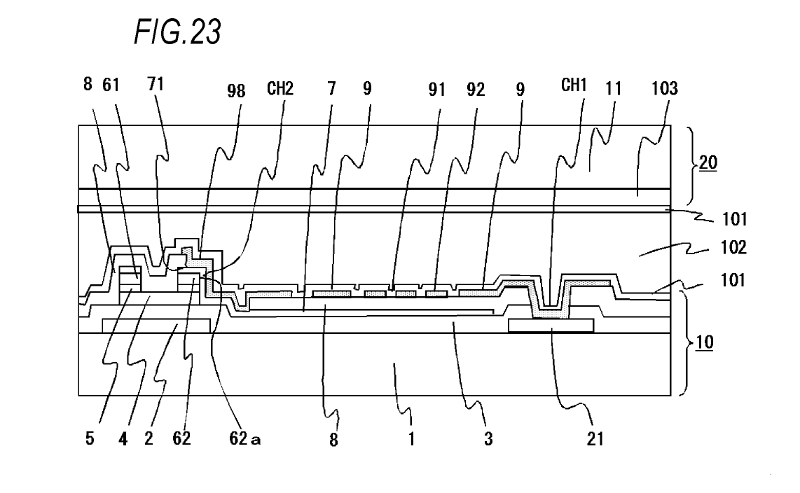

FIGS. 22 and 23 illustrate configuration of an array substrate according to the fourth embodiment. FIG. 22 shows the array substrate according to the fourth embodiment. FIG. 23 is a cross-sectional view taken along line M-M in FIG. 22. The fourth embodiment has configuration substantially same as those of the first to third embodiments but is characterized in that a semiconductor film and a drain electrode are formed within a region corresponding to a pattern of a gate electrode 2. In other words, the semiconductor film 4 and the drain electrode 62 are formed so as not to extend outside of the gate electrode 2 in a region where the drain electrode 62 connects with the lower electrode 7. As described in JP-A-2001-343669, this configuration can suppress display failure caused by light irradiation on the semiconductor film 4.

Accordingly, in the fourth embodiment, an electrode conductive film 71 covers a pattern end of the gate electrode 2 with interposing a gate insulation film 3, and each of the semiconductor film pattern and the drain electrode 62 does not cover the pattern end of gate electrode 2. However, also in the fourth embodiment, a coating conductive film 98 covers a pattern end of the drain electrode like the first to third embodiments. Further, in the fourth embodiment, when the array substrate is formed by a manufacturing method similar to that of the second embodiment, the electrode conductive film 71 is also formed to cover a step part of the semiconductor film, an ohmic-contact film and the drain electrode.

The coating conductive film 98 may be formed to cover a step part at the pattern end of the gate electrode 2 so long as this film is formed on the electrode conductive film 71. In this case, if an opening CH2 is formed at a portion where the electrode conductive film 71 extends over the step part at the pattern end of the gate electrode 2, as the electrode conductive film 71 is covered by the coating conductive film 98 also at the step part of the gate electrode 2, the coverage property of the conductive film can be improved. Although the fourth embodiment relates to a case where this disclosure is applied to a structure capable of suppressing light irradiation on the semiconductor film 4, the effects of this disclosure can be achieved also in the configuration of the fourth embodiment.

### Fifth Embodiment

In the first embodiment, an edge in the scanning wiring direction of the pattern end 62a of the drain electrode 62 is linear in a manner of extending in parallel to an edge in the scanning wiring direction of a pattern end of the drain electrode 62 on the channel part 41 side. However, this disclosure is not limited thereto.

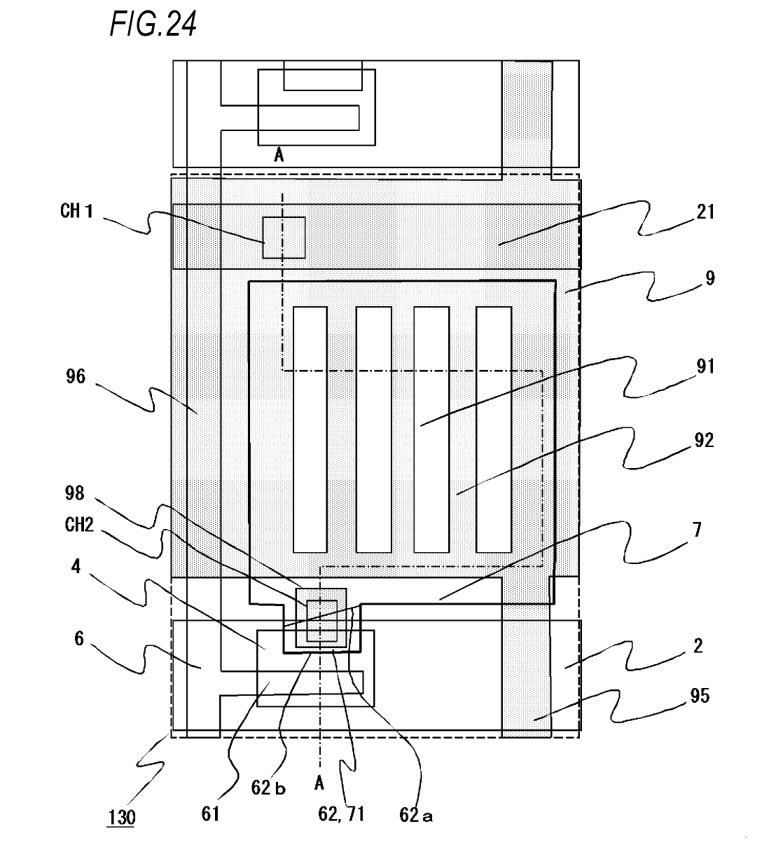

As shown in FIG. 24, an edge in the scanning wiring direction of a pattern end 62a may extend in an opening CH2 in a direction inclined with respect to the extending direction of the edge in the scanning wiring direction of a pattern end of the drain electrode 62 on the channel part 41 side. According to this configuration, as a length in the scanning wiring direction of a region where an electrode conductive film 71 covers a step part of the pattern end 62a becomes longer as compared with the configurations of the first to fourth embodiments, the coverage property of a coating conductive film 98 can be further improved.

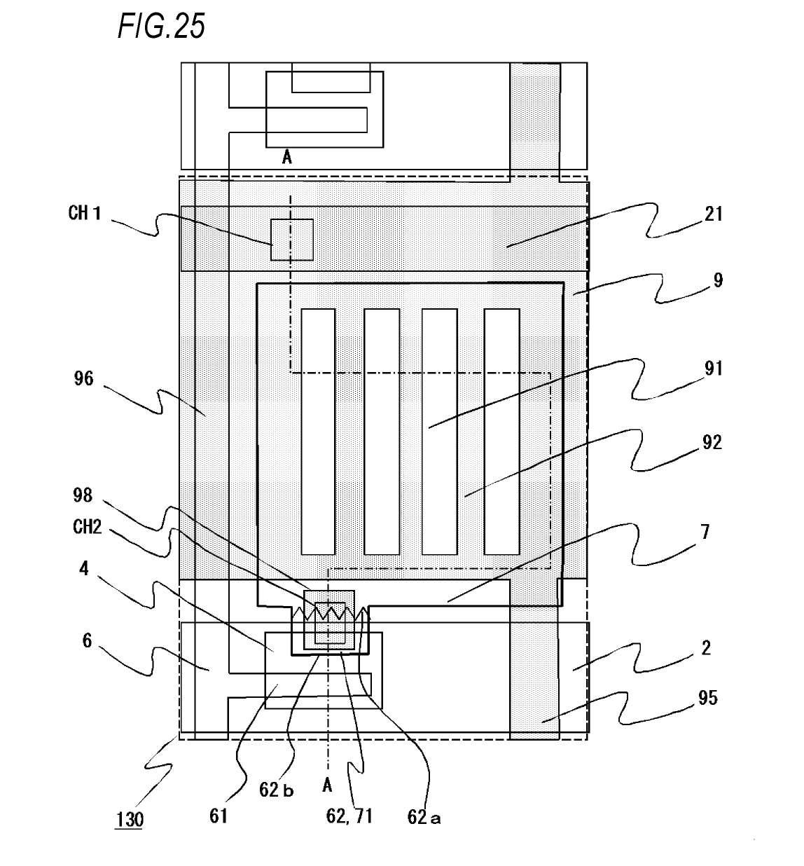

Alternatively, in the opening CH2, the shape of the edge of the pattern end 62a of the drain electrode 62 is not limited to be linear but may have at least one of bent point and inflection point. According to this configuration, since a length of the region where the electrode conductive film 71 covers the step part becomes further longer, the coverage property of the coating conductive film 98 can be furthermore improved. As shown in FIG. 25, the shape of the edge of the pattern end 62a may have a saw-tooth appearance or be a suitable combination of curves and straight lines. In other words, the shape of the edge of the pattern end may have plural bent portions or plural inflection points. Also, the pattern end 62b at the channel part may have a liner shape.

### Sixth Embodiment

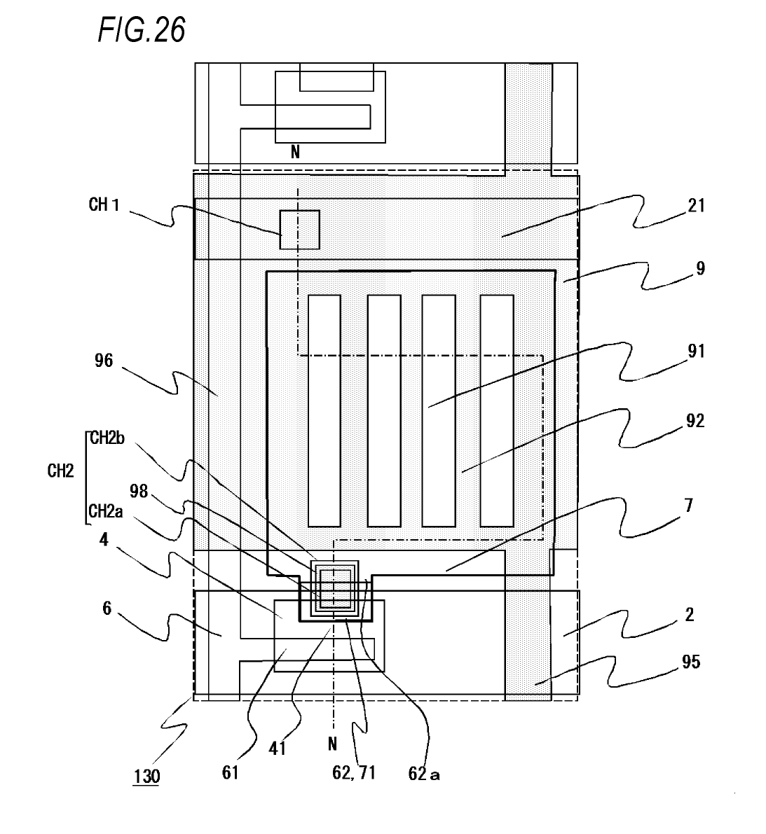

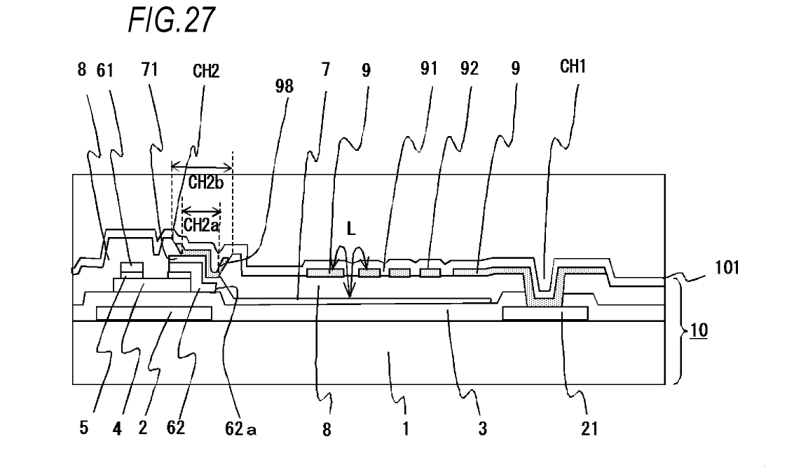

FIGS. 26 and 27 illustrate the sixth embodiment. FIG. 27 is a cross-sectional view taken along line N-N in FIG. 26. This embodiment is characterized in that a coating conductive film 98 is formed only in an opening CH2. The opening CH2 opens at an interlayer insulation film 8, and a bottom face of this opening contacts an electrode conductive film 71 to form an inner circumferential part CH2a. The opening has a conical shape and has a tapered shape in its section in a manner where an area of an outer circumferential part CH2b opened at an upper surface of the interlayer insulation film 8 is larger than the area of the inner circumferential part.

The configuration of this embodiment is characterized in that the outer circumferential part CH2b of the opening CH2 contains a pattern of the coating conductive film 98 and the pattern of the coating conductive film 98 contains the inner circumferential part CH2a as an edge of the bottom face of the opening CH2. Strictly concerning the upper surface of the interlayer insulation film 8, the coating conductive film 98 is formed within a concentric-circular toroidal region surrounded by the inner circumferential part CH2a and the outer circumferential part CH2b of the opening CH2. According to this configuration, the coverage property of the coating conductive film 98 at the step part of the pattern end 62a can be improved and probability of short-circuit between the pattern of the coating conductive film 98 and the upper electrode 9 can be suppressed.

### Seventh Embodiment

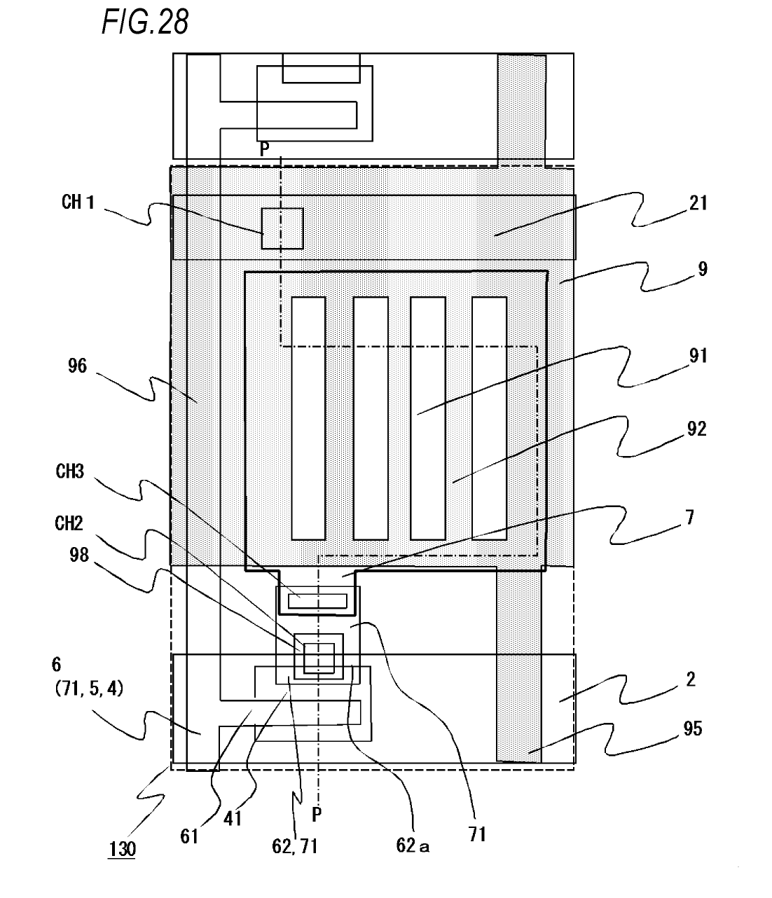

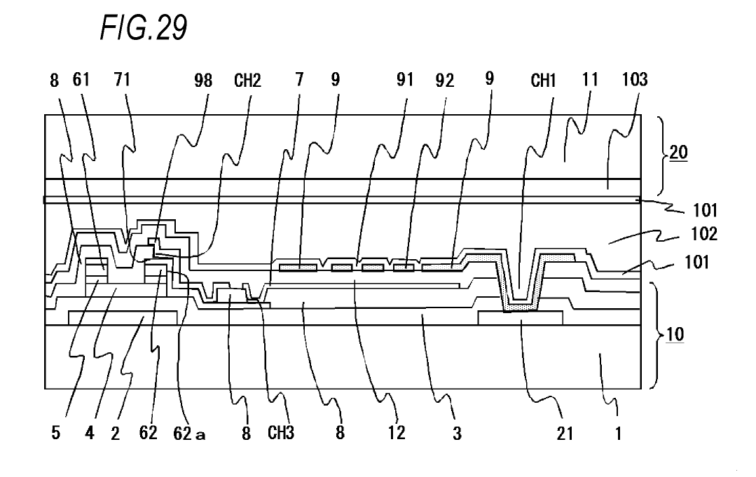

FIGS. 28 and 29 show the seventh embodiment. FIG. 28 shows an array substrate according to the seventh embodiment. FIG. 29 is a cross-sectional view taken along line P-P in FIG. 28. This embodiment is characterized in that an electrode conductive film 71 and a lower electrode 7 are formed in different layers with interposing an interlayer insulation film 8 and connected to each other via a contact hole which is opened at the interlayer insulation film 8. This embodiment will be explained with reference to FIGS. 28 and 29.

The electrode conductive film 71 is laminated on a drain electrode 62 to also cover a pattern end 62a and extended to a pixel region. The pixel region is a region surrounded by a scanning wiring 2 and a signal wiring 6, and represents the region occupied by the pixel electrode 7 in the first embodiment. The pixel region in the seventh embodiment contains a transmissive region for passing a visible light.

The interlayer insulation film 8 is formed to cover the drain electrode 62 and the electrode conductive film 71. The lower electrode 7 is formed on the interlayer insulation film 8. The lower electrode 7 and the electrode conductive film 71 are connected via a contact hole CH3 opened at the interlayer insulation film 8 in the pixel region. Thus, the lower electrode 7 is electrically connected to the drain electrode 62 and acts as the pixel electrode.

Similarly to the first embodiment, an opening CH2 is opened at the interlayer insulation film 8 on the pattern end 62a, and a coating conductive film 98 is formed to cover the opening CH2. The coating conductive film 98 and the lower electrode 7 are formed by the same layer. The coating conductive film 98 may be electrically separated from or connected to the lower electrode 7.

An inter-electrode insulation film 12 as the third insulation film is provided to cover the coating conductive film 98, the lower electrode 7 and the interlayer insulation film 8. An upper electrode 9 is formed on the inter-electrode insulation film 12. The upper electrode 9 is connected to a common wiring 21 via a common contact hole CH1 opened at the inter-electrode insulation film 12, the interlayer insulation film 8 and a gate insulation film 3, and applied with a reference voltage. Similarly to the first embodiment, liquid crystal molecules of liquid crystal 102 is driven by generating fringe electric field between slit-shaped branched electrode parts 92 of the upper electrode 9 and the lower electrode 7 via the inter-electrode insulation film 12 exposed at gap parts 91.

In a case where the lower electrode 7 and the drain electrode 62 are formed in the different layers with interposing the insulation film like the seventh embodiment, generally in most cases, a metal film pattern constituting the drain electrode is extended from the drain electrode 62 into the pixel region and connected to the lower electrode via the contact hole within the pixel region.

In the case of extending the metal film pattern constituting the drain electrode into the pixel region as described above, a sufficient area for electrical connection with the lower electrode can be secured. However, in a case of a liquid crystal display device of transmissive type, since the metal film pattern shields light passing through the pixel electrode as the lower electrode, a light transmission rate of the display device deteriorates.

In the seventh embodiment, as shown in FIG. 29, since the lower electrode is connected to the conductive film via the contact hole CH3 formed within the pixel region, a sufficient area for the electrical connection can be secured. Further, since the electrode conductive film 71 is formed by a transparent conductive film, the electrode conductive film does not shield light passing through the lower electrode as the pixel electrode.

Further, in a case where the drain electrode 62 is formed by a metal film mainly made of aluminum, chrome or the like and the metal film is extended into the pixel region, a transparent conductive film is formed on the metal film being a lower layer to ensure the electrical connection therebetween. However, in this case, a natural oxide film formed on the surface of the metal film interferes the electrical connection. In contrast, according to the seventh embodiment, since the electrode conductive film 71 extending from the drain electrode to the pixel region is formed by the transparent conductive film, good electrical connection with the lower electrode also formed by a transparent conductive film can be ensured.

The interlayer insulation film 8 in the seventh embodiment is preferably an inorganic insulation film made of SiN, SiO2, etc., with a thickness from 0.1 to 0.5 μm. The interlayer insulation film may be formed by sputtering or a CVD method.

In contrast, in a case where the interlayer insulation film 8 is formed by a resin film, a film thickness thereof usually exceeds 1 μm. Thus, since a rubbing process cannot be performed sufficiently on an orientation film (not shown) for orientating the liquid crystal molecules, light leakage may occur at a time of displaying black and then contrast may deteriorate. In order to suppress the light leakage, a film made of material capable of shielding light such as a metal film is suitable as the electrode conductive film 71. In contrast, in a case of not requiring to consider the light leakage upon displaying black, a resin film may be used as the interlayer insulation film 8 and a transparent conductive film may be used as the electrode conductive film 71.

In this embodiment, although the pixel region contains the transmissive region, the pixel region may also contain a shielding region not passing light. The configuration according to this embodiment may be applied to an array substrate of a liquid crystal display device of semi-transmissive type. In this case, the contact hole CH3 is formed within the transmissive region.

The seventh embodiment has the aforesaid effects and also has effects of improving the coverage property of the electrode conductive film 71 at the pattern end 62a of the drain electrode like the first embodiment.

In the aforesaid embodiments, although the explanation is made as to the case where the driving circuit is the COG mounting type, this disclosure can also be applied to a driving circuit of TAB (Tape Automated Bonding) mounting type or a liquid crystal display device containing a driving circuit formed by TFTs on an array substrate.

The aforesaid embodiments may be suitably combined. Further each of the embodiments may be suitably combined with a known structure or method. For example, a manufacturing method described in JP-A-2001-339072 may be applied to the first embodiment. For example, in the photoengraving process at the time of patterning the second metal film, a process using a so-called half tone technique may be applied in which after patterning the second metal film, the semiconductor film, etc. after forming resists having different thicknesses, the resists are thinned to separate the source electrode and the drain electrode, thereby forming a channel in the semiconductor layer.

Further the color filter and the shielding film may be provided not on the counter substrate but on the array substrate. The common wiring may be formed in the same layer as the lower electrode or the upper electrode.

What is claimed is:

1. An array substrate, comprising:
a substrate;
a scanning wiring and a signal wiring, which are provided to the substrate and cross to each other;
a switching element, which is connected to the scanning wiring and the signal wiring;
an electrode conductive film, which covers an upper surface of a drain electrode and an end portion of the drain electrode of the switching element and extends to form a lower electrode;
an interlayer insulation film, which covers the switching element and the electrode conductive film and has an opening which exposes at least a part of the end portion of the drain electrode; and
a coating conductive film, which is formed on the interlayer insulation film and covers the opening to cover the at least part of the end portion of the drain electrode.

2. The array substrate according to claim 1, further comprising:
an upper electrode, which is made of a transparent conductive film and is formed on the interlayer insulation film.

3. The array substrate according to claim 2,
wherein a reference voltage is applied to the upper electrode.

4. The array substrate according to claim 1, further comprising:
a semiconductor film which is formed below the drain electrode in a manner where a position of a pattern end of the semiconductor film coincides with a position of the end portion of the drain electrode.

5. The array substrate according to claim 1,
wherein a width of the drain electrode in a region at a channel part is smaller than a width of the drain electrode in a region where the drain electrode crosses an edge of the scanning wiring.

6. The array substrate according to claim 1,
wherein in a region where the drain electrode connects with the lower electrode, the semiconductor film and the drain electrode is formed within the scanning wiring to not cross an edge of the scanning wiring.

7. The array substrate according to claim 1,
wherein an extending direction of an edge of the pattern end of the drain electrode is not in parallel to an extending direction of an edge of a pattern end of the drain electrode on the channel side.

8. The array substrate according to claim 1,
wherein the end portion of the drain electrode has at least one of bent point and inflection point in the opening.

9. The array substrate according to claim 1,
wherein the electrode conductive film covers an inner circumferential part of the opening and do not extend outside of an outer circumferential part of the opening.

10. The array substrate according to claim 1,
wherein the opening exposes the at least a part of the end portion of the drain electrode via the electrode conductive film.

11. A liquid crystal display device including:
the array substrate according to claim 1.
